(19) United States
(12) Patent Application Publication
(10) Pub. No.: US 2023/0336013 A1
(43) Pub. Date: Oct. 19, 2023

(54) ADAPTING A BATTERY CHARGING PROFILE BASED ON NORMAL OPERATION OF A BATTERY-POWERED DEVICE

(71) Applicant: Cirrus Logic International Semiconductor Ltd., Edinburgh (GB)

(72) Inventors: Emmanuel A. MARCHAIS, Dripping Springs, TX (US); Eric J. KING, Austin, TX (US); John L. MELANSON, Austin, TX (US)

(73) Assignee: Cirrus Logic International Semiconductor Ltd., Edinburgh (GB)

(21) Appl. No.: 18/295,530

(22) Filed: Apr. 4, 2023

Related U.S. Application Data
(60) Provisional application No. 63/332,044, filed on Apr. 18, 2022.

(51) Int. Cl. G01R 31/367; G01R 31/389; H02J 7/00

(52) U.S. Cl. CPC H02J 7/0068; G01R 31/367; G01R 31/389

(57) ABSTRACT

A method of adapting a battery charging profile of a battery may include monitoring one or more parameters associated with the battery during normal operation of a device powered from the battery and while the battery is simultaneously charged by a charger and is discharged by a dynamic system load of the device, determining an impedance of the battery based on the one or more parameters, determining a condition of the battery based on the impedance and the one or more parameters, and adapting the battery charging profile based on the condition.

### RELATED APPLICATION

The present disclosure claims priority to U.S. Provisional Pat. Application Serial No. 63/332,044, filed Apr. 18, 2022, which is incorporated by reference herein in its entirety.

### FIELD OF DISCLOSURE

The present disclosure relates in general to circuits for electronic devices, including without limitation personal devices such as wireless telephones and media players, and more specifically, to a battery charging system wherein a battery charging profile is adapted based on in-situ measured parameters when a battery-powered device is in normal operation.

### BACKGROUND

Portable electronic devices, including wireless telephones, such as mobile/cellular telephones, tablets, cordless telephones, mp3 players, smart watches, health monitors, and other consumer devices, are in widespread use. Such a portable electronic device may include a battery (e.g., a lithium-ion battery) for powering components of the portable electronic device. Typically, such batteries used in portable electronic devices are rechargeable, such that when charging, the battery converts electrical energy into chemical energy which may later be converted back into electrical energy for powering components of the portable electronic device.

Rechargeable batteries are often charged in accordance with a charging profile, to enable effective charging and operation of such batteries.

### SUMMARY

In accordance with the teachings of the present disclosure, one or more disadvantages and problems associated with existing approaches to battery charging may be reduced or eliminated.

In accordance with embodiments of the present disclosure, a method of adapting a battery charging profile of a battery may include monitoring one or more parameters associated with the battery during normal operation of a device powered from the battery and while the battery is simultaneously charged by a charger and is discharged by a dynamic system load of the device, determining an impedance of the battery based on the one or more parameters, determining a condition of the battery based on the impedance and the one or more parameters, and adapting the battery charging profile based on the condition.

In accordance with these and other embodiments of the present disclosure, a system for adapting a battery charging profile of a battery may include a monitoring circuit configured to monitor one or more parameters associated with the battery during normal operation of a device powered from the battery and while the battery is simultaneously charged by a charger and is discharged by a dynamic system load of the device and a battery condition estimator configured to determine an impedance of the battery based on the one or more parameters, determine a condition of the battery based on the impedance and the one or more parameters, and adapt the battery charging profile based on the condition.

Technical advantages of the present disclosure may be readily apparent to one skilled in the art from the figures, description and claims included herein. The objects and advantages of the embodiments will be realized and achieved at least by the elements, features, and combinations particularly pointed out in the claims.

It is to be understood that both the foregoing general description and the following detailed description are examples and explanatory and are not restrictive of the claims set forth in this disclosure.

### BRIEF DESCRIPTION OF THE DRAWINGS

A more complete understanding of the present embodiments and advantages thereof may be acquired by referring to the following description taken in conjunction with the accompanying drawings, in which like reference numbers indicate like features, and wherein:

FIG. 1 illustrates an example block diagram of selected components of a system for charging a battery of an electronic device, in accordance with embodiments of the present disclosure;

FIG. 2 illustrates an example of a charging profile of a battery of a battery-powered device, in accordance with embodiments of the present disclosure;

FIG. 3 illustrates example charging waveforms of a USB-PD wall charger charging a smart phone, in accordance with embodiments of the present disclosure;

FIG. 4 illustrates an example charging profile utilizing a battery test circuit to momentarily discharge a battery during a charge of a battery-powered device, in accordance with embodiments of the present disclosure; and

FIG. 5 illustrates a broadband dynamic load from a smartphone executing a video-playback application, in accordance with embodiments of the present disclosure.

### DETAILED DESCRIPTION

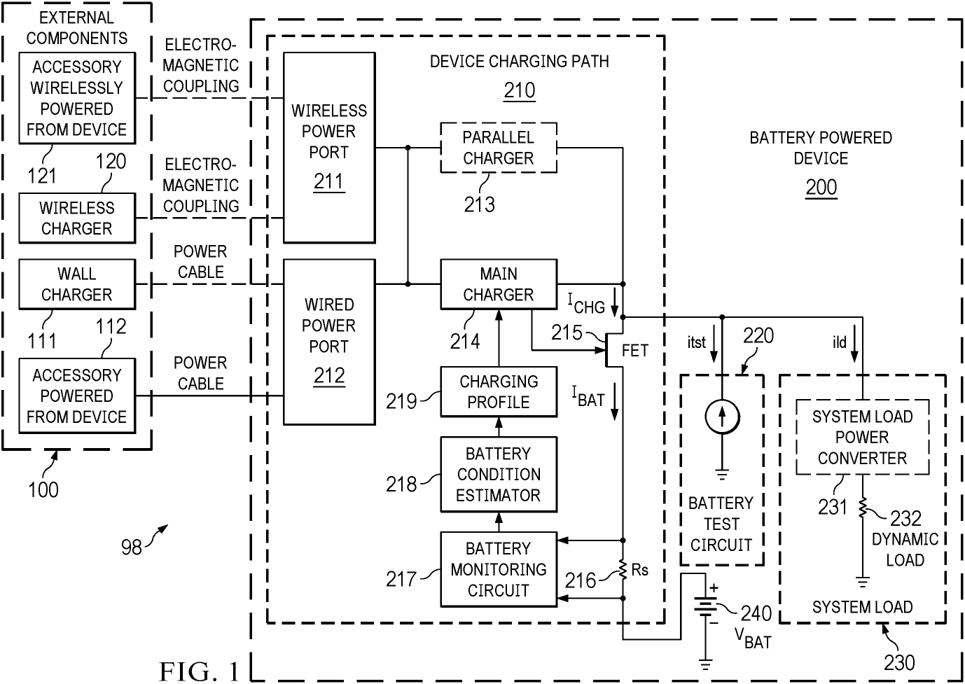

FIG. 1 illustrates an example block diagram of selected components of a system 98 for charging a battery 240 of a battery-powered device 200, in accordance with embodiments of the present disclosure. Battery-powered device 200 may comprise any suitable electronic device, including without limitation a mobile phone, smart phone, tablet, laptop/notebook computer, media player, handheld, smart watch, gaming controller, etc.

As shown in FIG. 1, one or more external components 100 may be wirelessly coupled or coupled via a wire or cable to battery-powered device 200. Such one or more external components 100 may include an external charger, such as a wall charger 111 and/or a wireless charger 120. Such one or more external components 100 may additionally or alternatively include an accessory 112 powered from battery-powered device 200 (e.g., an earbud charging case) and/or an accessory 121 wirelessly powered from battery-powered device 200 (e.g., a smartwatch). As also shown in FIG. 1, battery-powered device 200 may include a device charging path 210 to an internal battery 240 and a power path from battery 240 to a system load 230 of battery-powered device 200. Such system load 230 may include a processor, display, audio speaker, and/or one or more other electric or electronic components.

Battery 240 may include any system, device, or apparatus configured to convert chemical energy stored within battery 240 to electrical energy. For example, in some embodiments, battery 240 may be integral to battery-powered device 200, and battery 240 may be configured to deliver electrical energy to system load 230 and other components of battery-operated device 200. Further, battery 240 may also be configured to recharge, in which it may convert electrical energy received by battery 240 from main charger 214 and/or parallel charger 213 into chemical energy to be stored for later conversion back into electrical energy. As an example, in some embodiments, battery 240 may comprise a lithium-ion battery. Battery 240 may comprise a single cell, multiple cells in series, multiple cells in parallel, or a combination of multiple series and parallel cells.

Device charging path 210 may include a wired power port 212 configured to receive electrical energy from external wall charger 111 via a power cable and/or deliver electrical energy to accessory 112 via a power cable. Wired power port 212 may be a Universal Serial Bus (USB) Type C/Power Delivery (USB-C/PD) port and wall charger 111 may be a USB-PD charger with a programmable voltage between 5 volts and 20 volts. However, any suitable type of port and charger may be employed. Device charging path 210 may additionally or alternatively include a wireless power port 211 configured to receive electrical energy from external wireless charger 120 and/or deliver electrical energy to accessory 121 via wireless transmission. In some embodiments, wireless charger 120 may comprise a Qi-compliant charger.

Electrical energy received by device charging path 210 from either port 211, 212 may be converted to system-level electrical energy through a main charger 214 and/or through a second parallel charger 213 of battery-powered device 200. Main charger 214 may include any system, device, or apparatus configured to, when battery-powered device 200 is coupled to wall charger 111 and/or wireless charger 120, receive control signals and electrical energy from wall charger 111 and/or wireless charger 120 and control delivery of such energy to battery 240, system load 230, and/or other components of battery-powered device 200. For example, in some embodiments, main charger 214 may include an inductive-based power converter. However, any suitable regulator may be used to implement main charger 214, including without limitation a switched-capacitor regulator, a hybrid regulator, and a multi-level regulator. Parallel charger 213 may comprise a secondary inductive charger or switched-capacitor charger that supplements main charger 214 during high-rate charging phases.

Charging path 210 may deliver electrical energy of chargers 214, 213 simultaneously to system load 230 and battery 240. Electrical energy supplied to/from battery 240 may be decoupled from system power by controlling a power field-effect transistor (FET) 215 in series with battery 240. FET 215 may be configured to control an accurate current/voltage to battery 240 under operation of main charger 214.

In some instances, FET 215 may be fully turned on and power exchange among chargers 214, 213, system load 230, and battery 240 may be controlled purely by needs of system load 230, state of battery 240, and a current limit for chargers 214, 213. For example, during charging of battery 240, when the peak power needs of system load 230 exceed the charger current limit, battery 240 may momentarily supply power to system load 230. Battery 240 may receive electrical energy from external chargers 111, 120 or battery 240 may supply power back to accessories 112, 121. In the latter case, chargers 214, 213, wired power port 212, and/or wireless power port 211 may reverse their energy transfer.

When at least one of ports 211, 212 is reverse-charging (i.e., charging an external accessory 112 or 121), electrical energy may be transferred between ports 211, 212 (assuming at least one of ports 211 and 212 is supplying electrical energy to battery-powered device 200), or the accessory power may be supplied from battery 240 to a charging port 211, 212, or a combination of both. While an external charger 111, 120 is active, battery 240 may be simultaneously charged and discharged depending on power needs of system load 230 and the external accessory 112, 121.

Battery-powered device 200 may also include a battery monitoring circuit 217 configured to monitor a battery current I_{BAT} flowing through battery 240, a voltage V_{BAT} across battery 240, a temperature of battery 240, and/or other parameters associated with battery 240. Battery monitoring circuit 217 may be embedded within a battery pack of battery 240 or it may reside external to such battery pack. Battery-powered device 200 may also include a sense resistor 216 to allow battery monitoring circuit 217 to accurately monitor current battery current I_{BAT}.

Main charger 214 may charge battery 240 in accordance with a charging algorithm. In accordance with the charging algorithm, a battery condition estimator 218 may receive monitoring signals from battery monitoring circuit 217 to estimate a condition of battery 240, and adapt a charging profile 219 of the battery in response to the estimated battery condition, limits of the external charger 111, 120, and a charging policy. In some embodiments, main charger 214 may communicate with power elements of a charging system and power elements external to the charging system in order to define a power exchange among power elements.

Control of charging profile 219 may involve communication between main charger 214 and external charger 111, 120 to negotiate power transfer parameters. Control of charging profile 219 may further involve changing conversion ratios, current limits, and/or power limits of device chargers 214, 213, and/or adapting FET 215 for control of battery 240. Moreover, control of charging profile 219 may involve turning on or turning off elements of device charging path 210 and/or routing electrical energy through specific paths at different phases of a charging profile.

The estimation of battery condition by battery condition estimator 218 may include an estimation of state-of-charge (SOC) and/or state-of-health (SOH) of battery 240. In some embodiments, such estimation may include “coulomb counting,” the process of tracking an amount of electrical charge delivered to and drawn from battery 240. More sophisticated algorithms may include estimates of one or more detailed states of battery 240, such as an impedance of battery 240, an internal potential of battery 240, an estimate of an electro-chemical state of battery 240 (e.g., an ion concentration profile of battery 240), and/or other estimate of side-reactions to the main oxidation-reduction reaction of battery 240.

Although not shown in FIG. 1, battery 240 may also include other protection circuitry (e.g., a fuse, protection FETs, etc.).

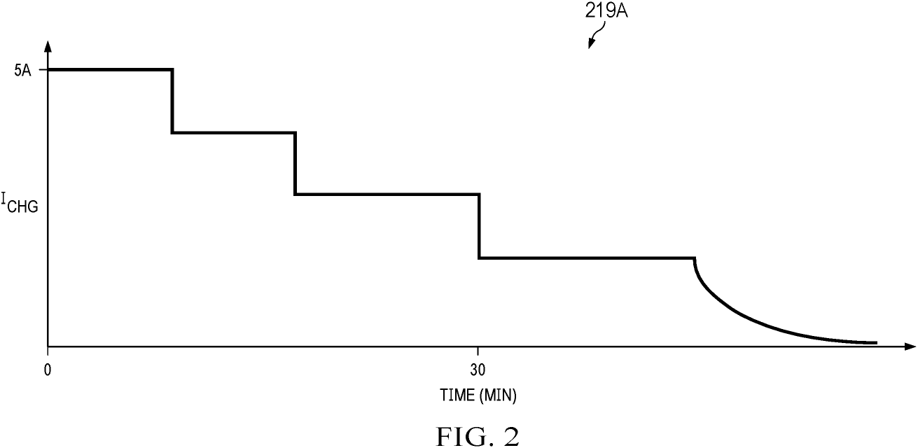

FIG. 2 illustrates an example of a charging profile 219A of battery 240 of battery-powered device 200, in accordance with embodiments of the present disclosure. In the example charging profile 219A depicted in FIG. 2, a charging current I_{CHG} delivered by chargers 214, 213 may have multiple constant-current steps followed by a final constant-voltage step. The timing of switching between current steps may be adapted based on the estimate of the condition of battery 240 generated by battery condition estimator 218, wherein the condition of battery 240 includes an SOC of battery 240.

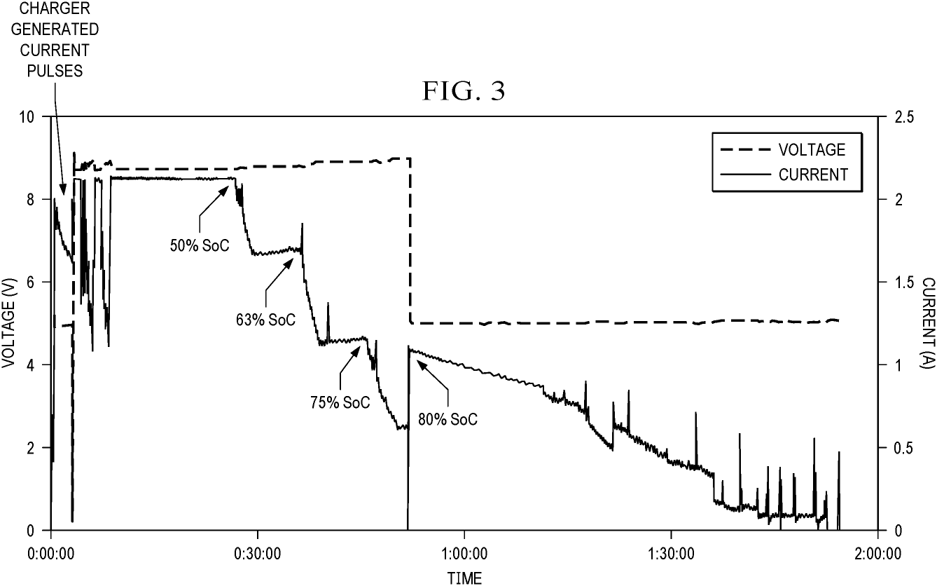

FIG. 3 illustrates example charging waveforms of a USB-PD wall charger (which may implement wall charger 111) charging a smart phone (which may implement battery-powered device 200), in accordance with embodiments of the present disclosure. In the example of FIG. 3, the charging algorithm implemented by battery condition estimator 218 controls charging profile 219 to generate current pulses on battery 240 at the beginning of charge, to determine a condition of the battery, wherein the condition is an impedance of battery 240. Battery condition estimator 240 may then adapt charging profile 219 based on estimation of this initial condition.

In some embodiments, battery-powered device 200 may include an auxiliary battery test circuit 220 to assist in determining a condition of battery 240. Battery test circuit 220 may include a resistor to ground, a current sink, a current source, and/or a combination of multiple elements. In some embodiments, battery test circuit 220 may be programmable under the control of main charger 214. For instance, the current level and timing of a current sink may be controlled by main charger 214. In some embodiments, battery test circuit 220 may apply current pulses of durations between 100 microseconds and 10 seconds to battery 240 to assist in determining an impedance of battery 240.

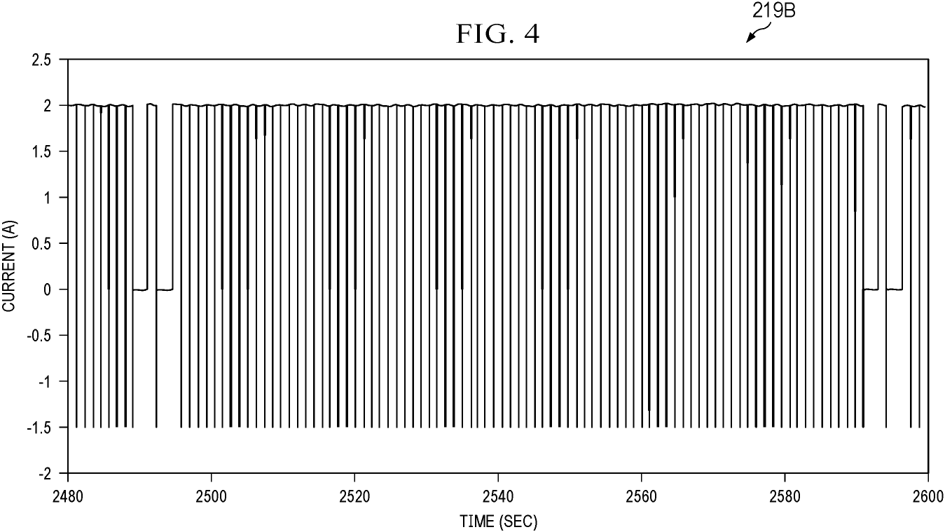

FIG. 4 illustrates example charging profile 219B utilizing battery test circuit 220 to momentarily discharge battery 240 during a charge of battery-powered device 200, in accordance with embodiments of the present disclosure. As shown in FIG. 4, battery test circuit 220 may transiently interrupt the current or load of battery 240 while battery 240 is charging. In charging profile 219B of FIG. 4, positive current charges battery 240 while negative current pulses discharge battery 240.

As also shown in FIG. 1, system load 230 of battery-powered device 200 may include a dynamic load 232 when battery-powered device 200 is in operation. For instance, if battery-powered device 200 is a smartphone, dynamic load 232 may include the load from an applications processor, a display driver, and/or an audio speaker. As also shown in FIG. 1, system load 230 may include a power converter 231 configured to convert power supplied by chargers 213, 214 and/or battery 240 into a regulated power expected by system load 230.

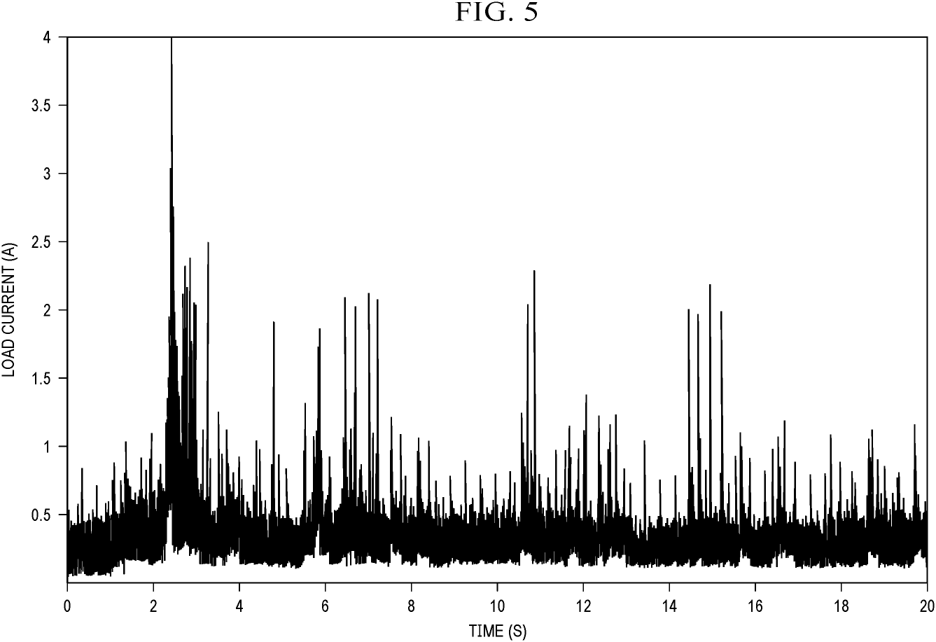

In some embodiments, dynamic load 232 may be a broadband dynamic load. For example, FIG. 5 illustrates a broadband dynamic load from a smartphone executing a video-playback application, in accordance with embodiments of the present disclosure. Battery condition estimator 218 may use any suitable approach for estimating impedance of battery 240 from monitored parameters sensed in connection with a broadband dynamic load. For example, systems and methods of estimating a battery impedance from a broadband dynamic load are disclosed in U.S. Pat. Application Serial No. 17/463,998 filed on Sep. 1, 2021 and U.S. Pat. Application Serial No. 17/463,980 filed on Sep. 1, 2021, both of which are incorporated by reference herein, in their entireties.

Embodiments of the present disclosure may combine one or more of the systems and methods described above in order to adapt a charging profile (e.g., charging profile 219) of a battery (e.g., battery 240) that is simultaneously charged by a charger (e.g., main charger 214, parallel charger 213) and discharged by a system load (e.g., system load 230). In accordance with embodiments of the present disclosure, battery condition estimator 218 may change a charging profile 219 to intentionally stimulate battery 240 to estimate an impedance of battery 240 and/or may control a dedicated battery test circuit 220 to intentionally create a transient load on battery 240 to determine an impedance of battery 240. However, other embodiments of the present disclosure may not require determination of impedance of battery 240 as a condition to adapt charging profile 219 of battery 240. Instead, such embodiments may rely on a broadband nature of dynamic system load 230 to stimulate battery 240 in order to estimate an impedance of battery 240 that is being simultaneously charged and discharged. A broadband dynamic load may enable estimation of impedance of battery 240 over a wide range of frequencies (e.g., ImHz to 1 MHz).

Utilizing the broadband nature of dynamic system load 232 may have many advantages. Non-limiting examples of such advantages over other approaches may include:
Reduction of circuitry (e.g., battery test circuit 220 may not be needed) and simplification of charging path requirements (e.g., no need to create current pulses through device charging path 210);
Power efficiency (e.g., no current sink needed for estimation purposes);
Reduction of charging time (e.g., no need to introduce charger current pulses at the beginning of charging);
More accurate estimation of battery condition because impedance can be estimated continuously from a broadband load as stimulus; and
Algorithmic benefits such as using battery impedance estimate to determine available power from battery 240.

Embodiments of the present disclosure provide systems and methods of adapting a battery charging profile of a battery based on measuring parameters associated with the battery during normal operation of the battery-powered device powered from the battery. As used herein, “normal operation” may be defined as the battery-operated device operating in accordance with its intended end-use functionality, such that parameters are measured and charging profiles are adapted in-situ, rather than parameters being measured or a charging profile being adapted offline or during a specialized calibration mode of the battery-powered device.

In some embodiments, systems and methods may include simultaneously charging a battery by a charger and discharging the battery by a dynamic system load. For at least a same time period, a device charging path for charging the battery by the charger and a loading path for discharging the battery by the dynamic system load are activated. A combination current and a battery terminal voltage from the activated charging and loading paths may be monitored. An impedance of the battery is determined from the combination current. A condition of the battery may be determined based on the combination current, the battery terminal voltage, and the determined impedance. Discharging the battery by the dynamic system load may indicate the powering of the charging system purely itself, and no additional stimulus may need to be added to the battery to identify the impedance.

Determining a condition of the battery may further involve reconfiguring elements of the charging path based on the determined impedance. The dynamic system load may be a broadband load. The system and method of adapting the battery charging profile of the battery may also comprise monitoring a temperature of the battery. The determination of the condition of the battery may be based on a monitored combination current, a monitored battery terminal voltage, and a monitored temperature of the battery. The determination of the battery condition may also involve utilizing coulomb counting in order to determine the condition of the battery. The determination of the battery condition further may be based on the determined impedance from the determining impedance step.

The battery charging profile may be adapted based on one or more of the following: the condition of the battery, a power capability of a power path; and/or user-dependent battery management conditions.

The system and method of adapting the battery charging profile may further comprise external power sinks coupled to the charger and power being supplied to the external power sinks through the charging path operating in a reverse direction. The charger may communicate with power elements of a charging system that encompasses the charging path and the loading path and also with external power elements to the charging system in order to define a power exchange.

The impedance of the battery may be determined by stimulating the battery with a transient event generated by a transient charging profile, and/or a transient power/source sink event from a dedicated battery test circuit, operated in conjunction with the dynamic system load.

As used herein, when two or more elements are referred to as “coupled” to one another, such term indicates that such two or more elements are in electronic communication or mechanical communication, as applicable, whether connected indirectly or directly, with or without intervening elements.

This disclosure encompasses all changes, substitutions, variations, alterations, and modifications to the example embodiments herein that a person having ordinary skill in the art would comprehend. Similarly, where appropriate, the appended claims encompass all changes, substitutions, variations, alterations, and modifications to the example embodiments herein that a person having ordinary skill in the art would comprehend. Moreover, reference in the appended claims to an apparatus or system or a component of an apparatus or system being adapted to, arranged to, capable of, configured to, enabled to, operable to, or operative to perform a particular function encompasses that apparatus, system, or component, whether or not it or that particular function is activated, turned on, or unlocked, as long as that apparatus, system, or component is so adapted, arranged, capable, configured, enabled, operable, or operative. Accordingly, modifications, additions, or omissions may be made to the systems, apparatuses, and methods described herein without departing from the scope of the disclosure. For example, the components of the systems and apparatuses may be integrated or separated. Moreover, the operations of the systems and apparatuses disclosed herein may be performed by more, fewer, or other components and the methods described may include more, fewer, or other steps. Additionally, steps may be performed in any suitable order. As used in this document, “each” refers to each member of a set or each member of a subset of a set.

Although exemplary embodiments are illustrated in the figures and described below, the principles of the present disclosure may be implemented using any number of techniques, whether currently known or not. The present disclosure should in no way be limited to the exemplary implementations and techniques illustrated in the drawings and described above.

Unless otherwise specifically noted, articles depicted in the drawings are not necessarily drawn to scale.

All examples and conditional language recited herein are intended for pedagogical objects to aid the reader in understanding the disclosure and the concepts contributed by the inventor to furthering the art, and are construed as being without limitation to such specifically recited examples and conditions. Although embodiments of the present disclosure have been described in detail, it should be understood that various changes, substitutions, and alterations could be made hereto without departing from the spirit and scope of the disclosure.

Although specific advantages have been enumerated above, various embodiments may include some, none, or all of the enumerated advantages. Additionally, other technical advantages may become readily apparent to one of ordinary skill in the art after review of the foregoing figures and description.

To aid the Patent Office and any readers of any patent issued on this application in interpreting the claims appended hereto, applicants wish to note that they do not intend any of the appended claims or claim elements to invoke 35 U.S.C. § 112(f) unless the words “means for” or “step for” are explicitly used in the particular claim.

What is claimed is:

1. A method of adapting a battery charging profile of a battery, comprising:
monitoring one or more parameters associated with the battery during normal operation of a device powered from the battery and while the battery is simultaneously charged by a charger and is discharged by a dynamic system load of the device;
determining an impedance of the battery based on the one or more parameters;
determining a condition of the battery based on the impedance and the one or more parameters; and
adapting the battery charging profile based on the condition.

2. The method of claim 1, wherein the one or more parameters comprise one or more of a current associated with the battery, a voltage associated with the battery, and a temperature associated with the battery.

3. The method of claim 1, wherein the condition is a state of charge of the battery.

4. The method of claim 1, wherein the condition is a state of health of the battery.

5. The method of claim 1, further comprising coupling external power sinks to the charger and supplying power to the external power sinks through the charger operating in a reverse direction.

6. The method of claim 1, wherein determining the impedance of the battery includes stimulating the battery with one or more of a transient event generated by a transient charging profile and a transient power source/sink event from a dedicated battery test circuit, operated in conjunction with the dynamic system load.

7. The method of claim 1, wherein the dynamic system load is a broadband load.

8. The method of claim 1, wherein determining the impedance of the battery comprises reconfiguring elements of a charging path of the device based on the impedance.

9. The method of claim 1, wherein adapting the battery charging profile further comprises adapting the charging profile based on one or more of a power capability of a power path of the device and user-dependent battery management conditions.

10. The method of claim 1, wherein the condition is an amount of electrical charge delivered to and drawn from the battery.

11. The method of claim 1, further comprising the charger communicating with power elements of a charging system and power elements external to the charging system in order to define a power exchange among power elements.

12. A system for adapting a battery charging profile of a battery, comprising:
a monitoring circuit configured to monitor one or more parameters associated with the battery during normal operation of a device powered from the battery and while the battery is simultaneously charged by a charger and is discharged by a dynamic system load of the device; and
a battery condition estimator configured to:
determine an impedance of the battery based on the one or more parameters;
determine a condition of the battery based on the impedance and the one or more parameters; and
adapt the battery charging profile based on the condition.

13. The system of claim 12, wherein the one or more parameters comprise one or more of a current associated with the battery, a voltage associated with the battery, and a temperature associated with the battery.

14. The system of claim 12, wherein the condition is a state of charge of the battery.

15. The system of claim 12, wherein the condition is a state of health of the battery.

16. The system of claim 12, further comprising external power sinks coupled to the charger and configured to supply power to the external power sinks through the charger operating in a reverse direction.

17. The system of claim 12, wherein determining the impedance of the battery includes stimulating the battery with one or more of a transient event generated by a transient charging profile and a transient power source/sink event from a dedicated battery test circuit, operated in conjunction with the dynamic system load.

18. The system of claim 12, wherein the dynamic system load is a broadband load.

19. The system of claim 12, wherein determining the impedance of the battery comprises reconfiguring elements of a charging path of the device based on the impedance.

20. The system of claim 12, wherein adapting the battery charging profile further comprises adapting the charging profile based on one or more of a power capability of a power path of the device and user-dependent battery management conditions.

21. The system of claim 12, wherein the condition is an amount of electrical charge delivered to and drawn from the battery.

22. The system of claim 12, further comprising the charger configured to communicate with power elements of a charging system and power elements external to the charging system in order to define a power exchange among power elements.
